(19) United States
(12) Patent Application Publication
(10) Pub. No.: US 2007/0134825 A1
(43) Pub. Date: Jun. 14, 2007

(54) Non-mask micro-flow etching process

(75) Inventors: Yuan-Xiang Zou, Tainan City (TW); Chia-Cheng Chuang, Tainan City (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 11/505,931

(22) Filed: Aug. 18, 2006

(30) Foreign Application Priority Data
Dec. 13, 2005 (TW) 094144025

(51) Int. Cl. H01L 21/66; H01L 21/302

(52) U.S. Cl. 438/18; 438/745

(57) ABSTRACT

A non-mask micro-flow etching process, comprising steps of: moving a nozzle capable of inkjetting an etchant over a substrate capable of being dissolved by the etchant; and inkjetting the etchant on the substrate from the nozzle. Means such as polishing and grinding are used to planarize the substrate by removing the flanges formed on the etched substrate. By the control of the size, the amount, the position, the moving direction and the traveling path of the nozzle, and the control of the droplet volume and the concentration of the etchant, as well as the matching of different substrates to a variety of etchants, micro-cups or micro-channels of any shape and formation can be formed to be adapted to electro-phoretic displays, semiconductor devices or any opto-electronic device requiring micro-structures.

### BACKGROUND OF THE INVENTION

1. Field of the Invention:

The present invention generally relates to a non-mask micro-flow etching process and, more particularly, to a process using a micro-flow etchant for forming micro-cups or micro-channels so as to simply the manufacturing process, shorten the manufacturing time, reduce the manufacturing cost, and enhance the precision and quality. The present invention can be adapted to electro-phoretic displays semiconductor devices or any opto-electronic device requiring micro-structures.

2. Description of the Prior Art:

The electro-phoretic display (EPD), also known as electronic paper, is a novel opto-electronic display technology. As shown in FIG. 1, which is a cross-sectional view showing the structure of a conventional EPD, a micro-cup matrix 11 is filled with a phoretic solution 12 comprising sol molecules 121. When the phoretic solution 12 is charged with an electric field, colorful sol molecules 121 move towards the electrode 13 since the colorful sol molecules 121 are charged. Therefore, the color of the colorful sol molecules 121 is shown. The micro-cup matrix 11 is required to be arbitrarily shaped and firmly constructed. Accordingly, the reliability of the EPD relies on the structure of the micro-cup matrix 11.

The micro-cup matrix 11 for the EPD is mainly manufactured using photolithography and micro embossing. The shortcomings of photolithography and micro embossing are expressed hereinafter.

Please refer to FIG. 2, which is a schematic diagram showing a process for manufacturing a micro-cup matrix by photolithography in U.S. Pat. No. 6,933,098 entitled “Process for roll-to-roll manufacture of a display by synchronized photolithographic exposure on a substrate web”. In FIG. 2, the process for manufacturing micro-cup matrix by photolithography comprising steps of photo-resist defining, UV exposure, wet etching, cleaning and baking. However, it has disadvantages such as:

(1) complicated manufacturing steps, resulting in a long manufacturing time;

(2) complicated manufacturing equipments, resulting in a high manufacturing cost;

(3) wet etching after UV exposure, resulting in a low manufacturing yield and a high cost in chemicals; and

(4) complicated steps in defining pixel cells.

Please refer to FIG. 3, which is a schematic diagram showing a process for defining pixel cells by photolithography in U.S. Pat. No. 6,933,098. In FIG. 3, when photolithography is used in colorful EPD manufacturing, the pixel cells R, G, B are defined using UV light 15 through different masks 14. Therefore, these complicated steps in defining pixel cells result in a low manufacturing yield and a high cost in masks.

Furthermore, please refer to FIG. 4, which is a schematic diagram showing a process for manufacturing a micro-cup matrix by micro embossing (roll-to-roll) in U.S. Pat. No. 6,930,818 entitled “Electrophoretic display and novel process for its manufacture”. The micro-cup matrix is formed using a precise mold 62 with only one step of embossing. Even though micro embossing can overcome the shortcomings of photolithography, it has disadvantages such as:

(1) poor quality due to contaminants remaining in the grooves of the mold since the mold grooves are compact (nano-mater scale);

(2) cleaning of the compact mold grooves resulting in high cost for EPD manufacturing;

(3) high manufacturing cost for the compact mold; and

(4) poor durability of the compact mold.

Therefore, to overcome the aforementioned shortcomings, there is need in providing a non-mask micro-flow etching process so as to simply the manufacturing process, shorten the manufacturing time, reduce tile manufacturing cost, and enhance the precision and quality.

### SUMMARY OF THE INVENTION

It is a primary object of the present invention to provide a non-mask micro-flow etching process using a micro-flow etchant for forming micro-cups or micro-channels so as to simply the manufacturing process, shorten the manufacturing time, reduce the manufacturing cost, and enhance the precision and quality. The present invention can be adapted to electro-phoretic displays, semiconductor devices or any opto-electronic device requiring micro-structures.

In order to achieve the foregoing object, the present invention provides a non-mask micro-flow etching process, comprising steps of: (a) moving at least a nozzle capable of inkjetting an etchant over a substrate capable of being dissolved by the etchant; and (b) inkjetting the etchant on the substrate from the nozzle.

Preferably, the nozzle is moved to a pre-determined position over the substrate by optical alignment.

Preferably, the etchant comprises at least poly (3,4-ethylenedioxy-thiophene)/poly styrenesulfonate (PEDOT/PSS), methanol, ethanol, isopropanol, acetone and combination thereof.

Preferably, the bottom surface of the substrate is coated with a material undissolvable with the etchant.

Preferably, the nozzle has an adjustable inkjetting volume.

Preferably, the nozzle has an adjustable aperture.

Preferably, the nozzle is controllably moved when the nozzle is inkjetting the etchant.

Preferably, the nozzle is non-linearly moved.

Preferably, the nozzle is intermittently moved.

Preferably, a plurality of nozzles are provided.

Preferably, the plurality of nozzles are arranged irregularly.

Preferably, the plurality of nozzles inkjet asynchronously.

Preferably, the inkjetting volumes of the plurality of nozzles are different.

Preferably, the plurality of nozzles are moved asynchronously.

Preferably, the plurality of nozzles have different moving paths.

Preferably, the non-mask micro-flow etching process further comprises a step of: planarizing the substrate by a treatment so as to remove flanges formed on the etched substrate.

Preferably, the treatment is mechanical polishing, thermol-chemical polishing, ion beam polishing or laser polishing.

Preferably, the treatment is reactive ion etching.

Preferably, the treatment is abrasive solid particle impact.

Preferably, the treatment is abrasive grinding.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a cross-sectional view showing the structure of the a conventional EPD in the prior art;

FIG. 2 is a schematic diagram showing a process for manufacturing a micro-cup matrix by photolithography in U.S. Pat. No. 6,933,098;

FIG. 3 is a schematic diagram showing a process for defining pixel cells by photolithography in U.S. Pat. No. 6,933,098;

FIG. 4 is a schematic diagram showing a process for defining pixel cells by micro embossing in U.S. Pat. No. 6,930,818;

FIG. 5 is a schematic diagram showing a non-mask micro-flow etching process for forming a micro-cup structure according to the present invention;

FIG. 6 and FIG. 7 show a wet etching process according to the present invention;

FIG. 8 shows a polishing process according to the present invention

FIG. 9 shows another polishing process according to the present invention;

FIG. 10 is a cross-sectional diagram showing a micro-cup structure according to the present invention;

FIG. 11 is a schematic diagram showing a non-mask micro-flow etching process for forming a micro-channel structure according to the present invention; and

FIG. 12 is a cross-sectional diagram showing a micro-channel structure according to the present invention.

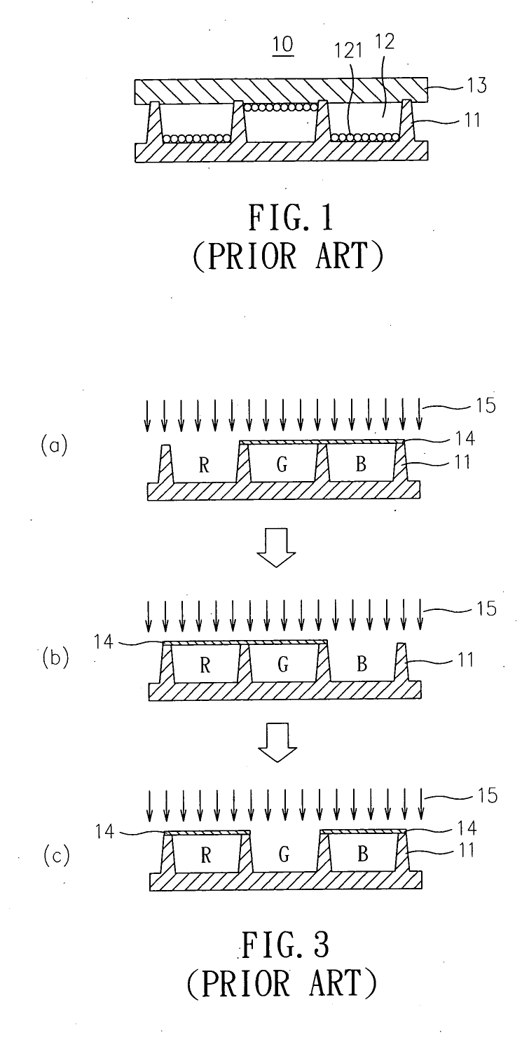

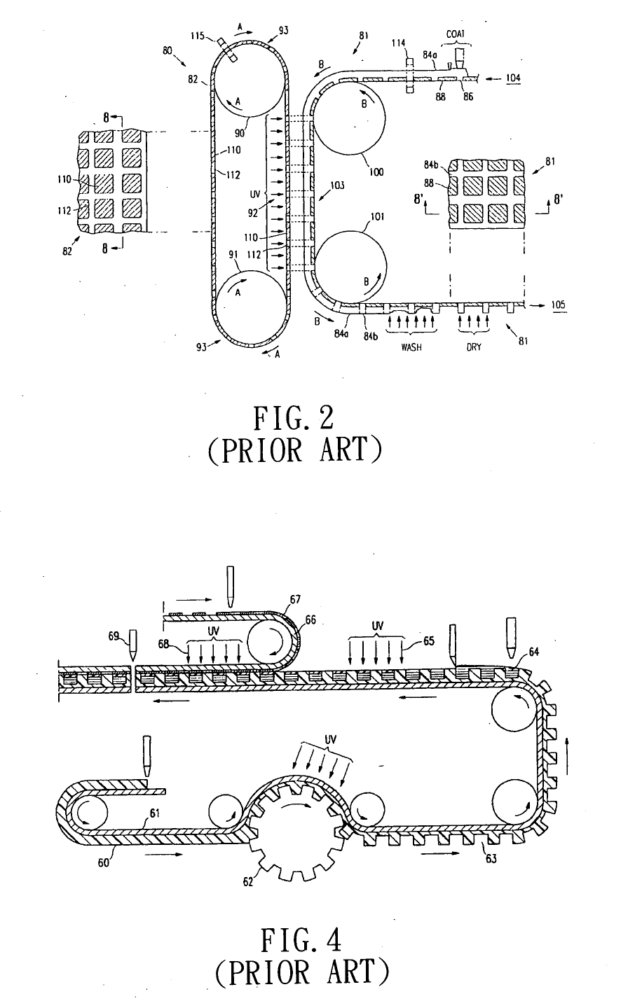

### DETAILED DESCRIPTION OF THE PREFERRED EMBODIMENT

The present invention providing a non-mask micro-flow etching process can be exemplified by the preferred embodiments as described hereinafter.

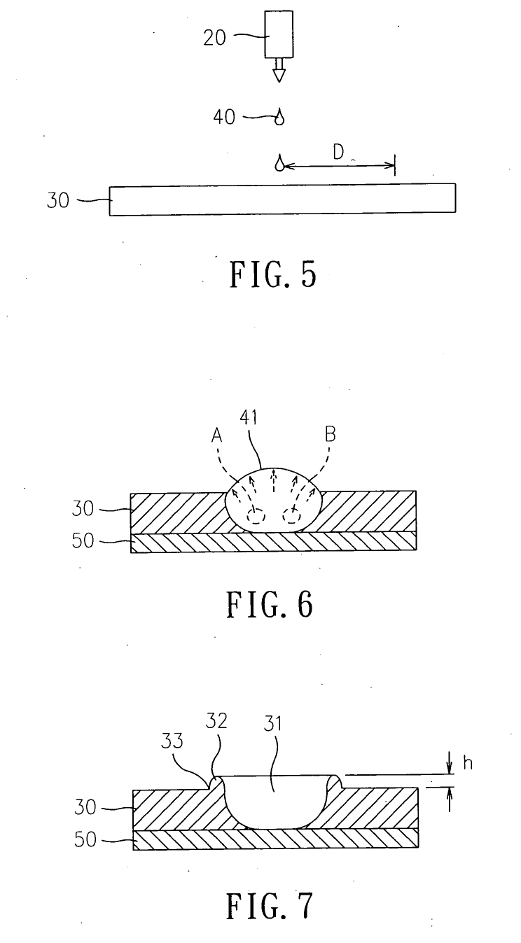

In 2003, Takeo Kawase discloses organic thin-film transistors by inkjet printing materials on a substrate in U.S. Patent Publication No. 2003/0060038 entitled “Forming Interconnects”. Advantageously, the present invention uses inkjet printing to form any devices requiring micro-structures. Please refer to FIG. 5, which is a schematic diagram showing a non-mask micro-flow etching process for forming a micro-cup structure according to the present invention. A nozzle 20 is capable of inkjetting an etchant 40, wherein the etchant comprises at least poly (3,4-ethylenedioxy-thiophene)/poly styrenesulfonate (PEDOT/PSS), methanol, ethanol, isopropanol, acetone and combination thereof. The nozzle 20 is moved to a pre-determined position over a substrate 30 by optical alignment. The substrate is capable of being dissolved by the etchant 40. The etchant 40 is then inkjetted on the substrate 30 from the nozzle 20. The afore-mentioned optical alignment process is advantageous in controlling the etchant 40 to be dripped on the substrate 30 within an inaccuracy D of 1 μm.

In FIG. 6, when a droplet 41 of the etchant 40 is dripped on the substrate 30, the substrate 30 is dissolvable in the droplet 41 so that the droplet 41 etches the substrate 30. To prevent the droplet 41 from over-etching the substrate 30, the bottom surface of the substrate 30 is coated with a material 50 undissolvable with the etchant 40. Moreover, the droplet 41 forms a semi-sphere on the substrate 30 due to surface tension so that a solute B is dissolved from the substrate 30 in addition to a solute A inherently in the droplet 41.

Since the surface vaporization rate of the droplet 41 is larger than the inner vaporization rate, the flow inside the droplet 41 is moving towards the surface of the droplet 41 so as to compensate for the loss due to the vaporization rate difference. This can be regarded as a net mass transfer effect oriented outwards so as to carry the solute A and the solute B outside of the droplet 41. Since the surface vaporization rate of the droplet 41 is larger than the inner vaporization rate, convection of the micro-flow inside the droplet 41 is induced by vaporization. The convection rate is expressed as:

$$v = \frac{1}{ρ rh} {\int }_{0}^{R} r [ {J}_{s} ( r ) \sqrt{1 + {( \frac{\partial h}{\partial r} )}^{2}} + ρ \frac{\partial h}{\partial t} ] ⅆ r$$

Since the convection effect induces the mass transfer effect inside the droplet 41, the solute with a smaller specific gravity will be carried out of the droplet 41. A diffusion effect induced by concentration difference is negligible because its influence is much smaller than that of the convection effect. The diffusion rate is expressed as:

$$c ( x , t ) = \frac{{c}_{s}}{2} [ 1 - \frac{2}{\sqrt{π}} erf ( \frac{x}{2 \sqrt{Dt}} ) ]$$

Moreover, if there is any difference of specific gravity between the solute A and the solute B, the solute with a larger specific gravity will deposit in the center of the droplet 41 because the gravity effect is more influential than the convection effect. Accordingly, a deposit is selected so as to form a desired micro-structure using such a phase separation effect. For example, a conductive micro-structure can be formed by selecting a conductive deposit and a luminescent micro-structure can be formed by selecting a fluorescent deposit.

Using the afore-mentioned mass transfer effect, diffusion effect and phase separation effect, a micro-cup structure 31 can be formed on the substrate 30 as shown in FIG. 7. After the dissolved material of the substrate 30 is transferred outside the droplet 41, the material deposits at the interface 33 between the droplet 41 and the substrate 30 and forms a flange 32 with a shape of a meteorite crater. As the number of the droplets 41 dripped on the substrate 30 increases, the depth as well as the height h of the flange 32 increases.

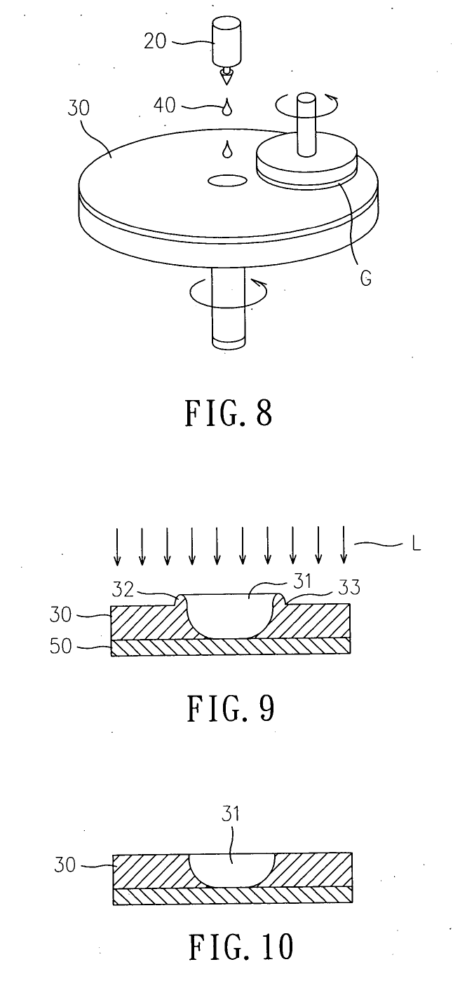

When the substrate 30 with the flange 32 is required to be mounted onto any other device, the combined device may suffer from the unsmooth interface if the height h of the flange 32 is relatively too large. In order to avoid device failure, a planarization treatment is required for the substrate 30 with a flange 32. The planarization treatment can be mechanical polishing implemented using a grinder G as shown in FIG. 8 or laser polishing implemented using an excimer laser L as shown in FIG. 9. Alternatively, planarization treatment can also be thermo-chemical polishing, ion beam polishing, reactive ion etching polishing, abrasive solid particle impact and abrasive grinding. After the planarization treatment, the micro-cup structure on the substrate has a planarized surface as shown in FIG. 10.

Accordingly, a micro-cup structure 31 can be formed using a nozzle 20 to inkjet an etchant 40 on the substrate 30 according to the present invention. Similarly, a plurality of nozzles 20 can be installed to form a plurality of micro-cups 31. Alternatively, a single nozzle 20 can be used to form a plurality of micro-cups 31 by intermittently moving the nozzle 20. Alternatively, a single nozzle 20 can also be used to form a plurality of micro-cups 31 by continuously moving the nozzle 20 and intermittently inkjetting the etchant 40. The arrangement of the plurality of micro-cups 31 can be controlled by the number of the nozzles 20, the positioning of the nozzles 20, the moving paths and moving distance of the nozzles 20. The height h as well as the diameter of the micro-cup 31 can be controlled by the matching condition of the etchant 40 and the substrate 30, the concentration of the etchant 40, the number of the droplets 41 and the aperture of the nozzles. Conventionally, the top view of a micro-cup is round and the aspect ratio is 1:20. However, in the present invention, the aspect ratio is improved to 1:10 and the micro-cup can be arbitrarily shaped.

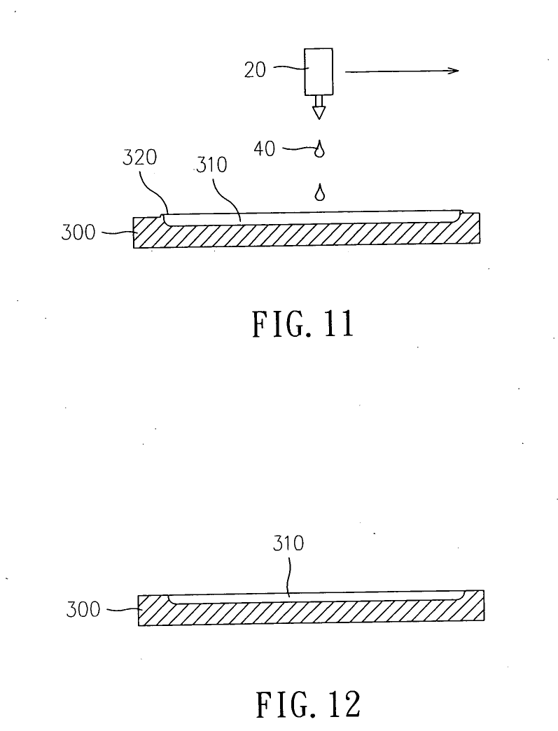

Please refer to FIG. 11, which is a schematic diagram showing a non-mask micro-flow etching process for forming a micro-channel structure according to the present invention. When the nozzle 20 continuously moves and inkjets the etchant 40, a micro-channel 310 with a shape of a groove can be formed on the substrate 300. An irregularly shaped micro-channel 310 can be formed if the nozzle 20 moves in an irregular path. Similarly, the flange 320 on the edge of the micro-channel 310 can be smoothed out by a planarization treatment using mechanical polishing, laser polishing, thermo-chemical polishing, ion beam polishing, reactive ion etching. polishinig, abrasive solid particle impact or abrasive grinding so that the micro-channel 310 on the substrate 300 has a planarized surface as shown in FIG. 12. Such a process can be used to deposit a micro-channel electrode for a semiconductor device.

According to FIG. 5 to FIG. 7, a conclusion is made to summarize a non-mask micro-flow etching process, comprising steps of:

(a) moving at least a nozzle 20 capable of inkjetting an etchant 40 over a substrate 30 capable of being dissolved by the etchant 40;

(b) inkjetting the etchant 40 on the substrate 30 from the nozzle 20; and

(c) planarizing the substrate by a treatment so as to remove flanges 32 formed on the etched substrate 30.

According to the above discussion, it is apparent that the present invention discloses a non-mask micro-flow etching process using inkjet printing, micro fluid dynamics, thermo-chemistry, material mechanics, optical alignment and phase separation so as to form micro-cups or micro-channels. The non-mask micro-flow etching process of the present invention is advantageous in that:

(1) The non-mask etching process is simple and requires low-cost equipments to complete the manufacture;

(2) The non-mask etching process can do without mass usage of chemicals and masks in conventional photolithography;

(3) The non-contact process can overcome the problems due to contaminaents remaining in the grooves of the mold since the mold grooves are compact;

(4) Optical alignment saves time and improves quality by preventing defects due to improper alignment;

(5) High precision in alignment results in high-quality flexible EPD's;

(6) Micro-structures such as micro-channels and micro-cups can be formed using the non-mask micro-flow etching process;

(7) Micro-cups with arbitrary shape and aspect ratio can be made so as to improve the quality of EPD's;

(8) The non-mask micro-flow etching process can be widely used to manufacture any opto-electronic device requiring micro-structures.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A non-mask micro-flow etching process, comprising steps of:
(a) moving at least a nozzle capable of inkjetting an etchant over a substrate capable of being dissolved by the etchant; and
(b) inkjetting the etchant on the substrate from the nozzle.

2. The non-mask micro-flow etching process as recited in claim 1, wherein the nozzle is moved to a pre-determined position over the substrate by optical alignment.

3. The non-mask micro-flow etching process as recited in claim 1, wherein the etchant comprises at least poly (3,4-ethylenedioxy-thiophene)/poly styrenesulfonate (PEDOT/PSS), methanol, ethanol, isopropanol, acetone and combination thereof.

4. The non-mask micro-flow etching process as recited in claim 1, wherein the bottom surface of the substrate is coated with a material undissolvable with the etchant.

5. The non-mask micro-flow etching process as recited in claim 1, wherein the nozzle has an adjustable inkjetting volume.

6. The non-mask micro-flow etching process as recited in claim 1, wherein the nozzle has an adjustable aperture.

7. The non-mask micro-flow etching process as recited in claim 1, wherein the nozzle is controllably moved when the nozzle is inkjetting the etchant.

8. The non-mask micro-flow etching process as recited in claim 7, wherein the nozzle is non-linearly moved.

9. The non-mask micro-flow etching process as recited in claim 7, wherein the nozzle is inter mittently moved.

10. The non-mask micro-flow etching process as recited in claim 1, wherein a plurality of nozzles are provided.

11. The non-mask micro-flow etching process as recited in claim 10, wherein the plurality of nozzles are arranged irregularly.

12. The non-mask micro-flow etching process as recited in claim 10, wherein the plurality of nozzles inkjet asynchronously.

13. The non-mask micro-flow etching process as recited in claim 10, wherein the inkjetting volumes of the plurality of nozzles are different.

14. The non-mask micro-flow etching process as recited in claim 10, wherein the plurality of nozzles are moved asynchronously.

15. The non-mask micro-flow etching process as recited in claim 10, wherein the plurality of nozzles have different moving paths.

16. The non-mask micro-flow etching process as recited in claim 10, further comprising a step of:
planarizing the substrate by a treatment so as to remove flanges formed on the etched substrate.

17. The non-mask micro-flow etching process as recited in claim 16, wherein the treatment is mechanical polishing, thermol-chemical polishing, ion beam polishing or laser polishing.

18. The non-mask micro-flow etching process as recited in claim 16, wherein the treatment is reactive ion etching.

19. The non-mask micro-flow etching process as recited in claim 16, wherein the treatment is abrasive solid particle impact.

20. The non-mask micro-flow etching process as recited in claim 16, wherein the treatment is abrasive grinding.
